(19) United States
(12) Patent Application Publication
(10) Pub. No.: US 2006/0231877 A1
(43) Pub. Date: Oct. 19, 2006

(54) Semiconductor device

(76) Inventors: Keiichi Takenaka, Kawasaki-shi (JP); Katsunori Yahashi, Yokohama-shi (JP); Itsuko Sakai, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/154,595

(22) Filed: Jun. 17, 2005

(30) Foreign Application Priority Data
Apr. 14, 2005 (JP) 2005-117043

(51) Int. Cl. H01L 29/772

(52) U.S. Cl. 257/296; 257/301

(57) ABSTRACT

A semiconductor device comprises a semiconductor substrate having a surface of a plane orientation {100}, and a plurality of memory cells formed on the semiconductor substrate. The memory cells each include a capacitor formed in a trench extending from the surface into the semiconductor substrate, and a transistor. The transistor has a first source/drain region connected to the capacitor, a second source/drain region formed apart from the first source/drain region as leaving an interval therebetween and connected to a bit line, and a gate electrode formed over the interval between the first and second source/drain regions and connected to a word line. A transverse section of at least part of the trench is tetragonal. Transverse sections of the trenches in the memory cells are tilted at the substantially same angle against a direction of extension of the word line.

### CROSS-REFERENCE TO RELATED APPLICATION

This application is based upon and claims the benefit of priority from the prior Japanese Patent Application No. 2005-117043, filed on Apr. 14, 2005; the entire contents of which are incorporated herein by reference.

### BACKGROUND OF THE INVENTION

1. Field of the Invention

The present invention relates to a semiconductor device such as a DRAM (Dynamic Random Access Memory) having trench capacitors.

2. Description of the Related Art

A DRAM is a semiconductor device that stores one bit information based on the quantity of charge accumulated in a capacitor. In the DRAM, leakage of charge accumulated in the capacitor inevitably occurs. Accordingly, prior to dissipation of charge from the capacitor, an operation is required to read out information once and write the same information. This is referred to as a refresh operation. Correct storage of information without excessive refresh operations requires the capacitor to have a larger capacitance. A capacitance C of the capacitor is represented by C=εS/d where ε denotes a dielectric constant of a dielectric film or capacitor insulator; S denotes a surface area of the capacitor insulator; and d denotes a thickness of the capacitor insulator. Therefore, the capacitance C is proportional to the surface area S of the capacitor insulator.

As the DRAM is pattered much finer, however, the capacitor formed two-dimensionally on a surface of a semiconductor substrate is prevented from having a larger surface area of the capacitor insulator. Accordingly, the capacitor can not have an increased capacitance. A trench is therefore etched in the semiconductor substrate to bury the capacitor therein, thereby elongating the capacitor in the vertical direction (for example, JP-A 2002-110942, FIG. 1 and JP-A 2003-7857, FIG. 16). This is effective to enlarge the surface area of the capacitor insulator to increase the capacitance of the capacitor.

The DRAM may comprise memory cells, each including a transistor and a capacitor that is buried in a trench formed below a word line adjacent to a word line for control of the transistor (for example, JP-A2000-91522, FIG. 25). A shortened distance between these word lines may reduce the margin of space between trenches and possibly result in incomplete separation between trenches.

### BRIEF SUMMARY OF THE INVENTION

According to an aspect of the present invention, there is provided a semiconductor device comprising a semiconductor substrate having a surface of a plane orientation {100}; and a plurality of memory cells formed on the semiconductor substrate. The memory cells each include a capacitor formed in a trench extending from the surface into the semiconductor substrate, and a transistor having a first source/drain region connected to the capacitor, a second source/drain region formed apart from the first source/drain region as leaving an interval therebetween and connected to a bit line, and a gate electrode formed over the interval between the first and second source/drain regions and connected to a word line. A transverse section of at least part of the trench is tetragonal. Transverse sections of the trenches in the memory cells are tilted at the substantially same angle against a direction of extension of the word line.

According to another aspect of the present invention, there is provided a semiconductor device comprising a semiconductor substrate having a surface of a plane orientation {111}; and a plurality of memory cells formed on the semiconductor substrate. The memory cells each including a capacitor formed in a trench extending from the surface into the semiconductor substrate, and a transistor having a first source/drain region connected to the capacitor, a second source/drain region formed apart from the first source/drain region as leaving an interval therebetween and connected to a bit line, and a gate electrode formed over the interval between the first and second source/drain regions and connected to a word line. A transverse section of at least part of the trench is hexagonal elongated in a direction of extension of the word line.

### BRIEF DESCRIPTION OF THE DRAWINGS

FIG. 1 is a schematic plan view of a memory cell array contained in a DRAM according to a first embodiment;

FIG. 2 is an equivalent circuit diagram of a memory cell shown in FIG. 1;

FIG. 3 is a longitudinal cross-sectional view of part of the memory cell array according to the first embodiment;

FIG. 4 is a transverse cross-sectional view taken along A1-A2 line in FIG. 3;

FIG. 5 is a transverse cross-sectional view taken along B1-B2 line in FIG. 3;

FIG. 6 is a first process diagram of a method of manufacturing the memory cell according to the first embodiment;

FIG. 7 is a second process diagram of the same method;

FIG. 8 is a third process diagram of the same method;

FIG. 9 is a fourth process diagram of the same method;

FIG. 10 is a fifth process diagram of the same method;

FIG. 11 is a sixth process diagram of the same method;

FIG. 12 is a seventh process diagram of the same method;

FIG. 13 is an eighth process diagram of the same method;

FIG. 14 is a ninth process diagram of the same method;

FIG. 15 is a tenth process diagram of the same method;

FIG. 16 is an eleventh process diagram of the same method;

FIG. 17 is a twelfth process diagram of the same method;

FIG. 18 is a thirteenth process diagram of the same method;

FIG. 19 is a fourteenth process diagram of the same method;

FIG. 20 is a fifteenth process diagram of the same method;

FIG. 21 is a sixteenth process diagram of the same method;

FIG. 22 is a seventeenth process diagram of the same method;

FIG. 23 is an eighteenth process diagram of the same method;

FIG. 24 is a nineteenth process diagram of the same method;

FIG. 25 is a plan view of a semiconductor substrate (wafer) for use in formation of the memory cell according to the first embodiment;

FIG. 26 is a plan view of the wafer of FIG. 25 at a 45°-rotated location in the x-y plane;

FIG. 27 is a plan view of the resist shown in FIG. 7;

FIG. 28 is a plan view of the mask shown in FIG. 9;

FIG. 29 is a transverse cross-sectional view of a lower portion of a trench according to a comparative example;

FIG. 30 is a transverse cross-sectional view of a lower portion of a trench according to a second embodiment;

FIG. 31 is a transverse cross-sectional view of an upper portion of the trench according to the second embodiment;

FIG. 32 is a plan view of a semiconductor substrate (wafer) for use in formation of a memory cell according to the second embodiment;

FIG. 33 is a plan view of the developed resist in the second embodiment;

FIG. 34 is a plan view of a silicon oxide film patterned with a mask of the resist of FIG. 33;

FIG. 35 is a longitudinal cross-sectional view of part of a memory cell array according to a third embodiment;

FIG. 36 is a first process diagram of a method of forming a trench according to the third embodiment; and

FIG. 37 is a second process diagram of the same method.

### DETAILED DESCRIPTION OF THE INVENTION

Embodiments of the present invention will now be described with reference to the drawings. In the figures, the parts same as or similar to those denoted with the reference numerals in the figure once described are given the same reference numerals and omitted from the following description.

### First Embodiment

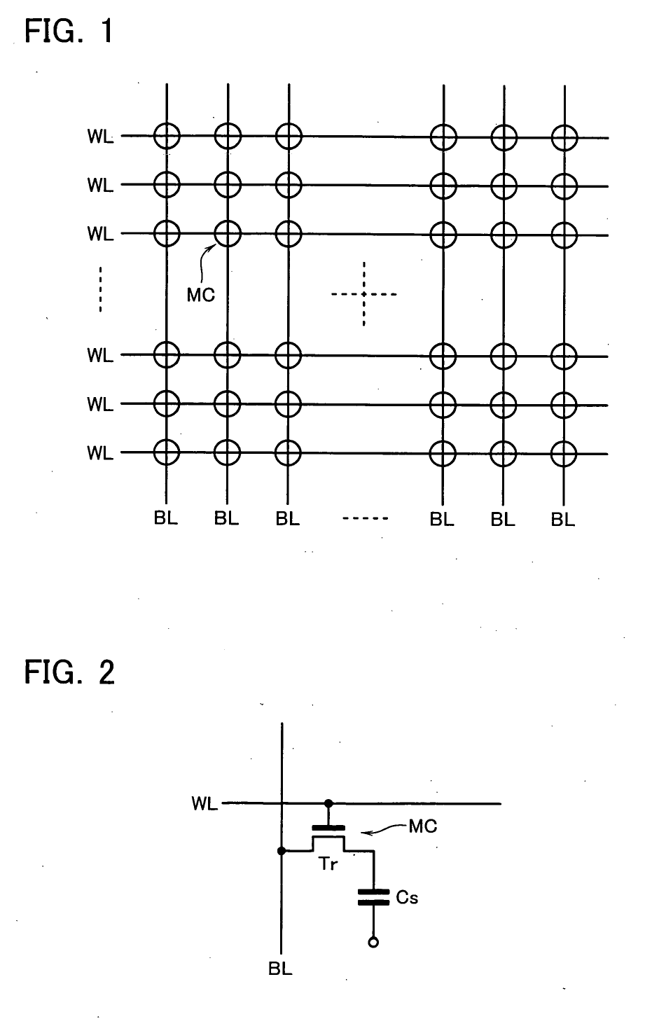

A semiconductor device according to a first embodiment is mainly characterized in a DRAM comprising memory cells each including a capacitor buried in a trench having a tetragonal transverse section, in which transverse sections of trenches are tilted at the substantially same angle against a direction of extension of a word line. As the premise for understanding this point, the DRAM or the semiconductor device according to the first embodiment is briefly described. FIG. 1 is a schematic plan view of a memory cell array contained in the DRAM according to the first embodiment.

The memory cell array includes a plurality of word lines WL laid in the row direction, a plurality of bit lines BL laid in the column direction, and a plurality of memory cells MC located at intersections of the word lines WL and the bit lines BL. A word line WL and a bit line BL are specified to select one memory cell MC for execution of reading or writing one bit information.

FIG. 2 is an equivalent circuit diagram of the memory cell MC shown in FIG. 1. The memory cell MC includes a MOS (Metal Oxide Semiconductor) transistor Tr and a capacitor Cs. The word line WL is selected to turn on the MOS transistor Tr at the gate and the selected bit line BL is set at a potential of “H” or “L”. As for the capacitor Cs of the selected memory cell MC, charge is accumulated therein in the case of “H” and pulled out therefrom in the case of “L”, thereby writing one bit information.

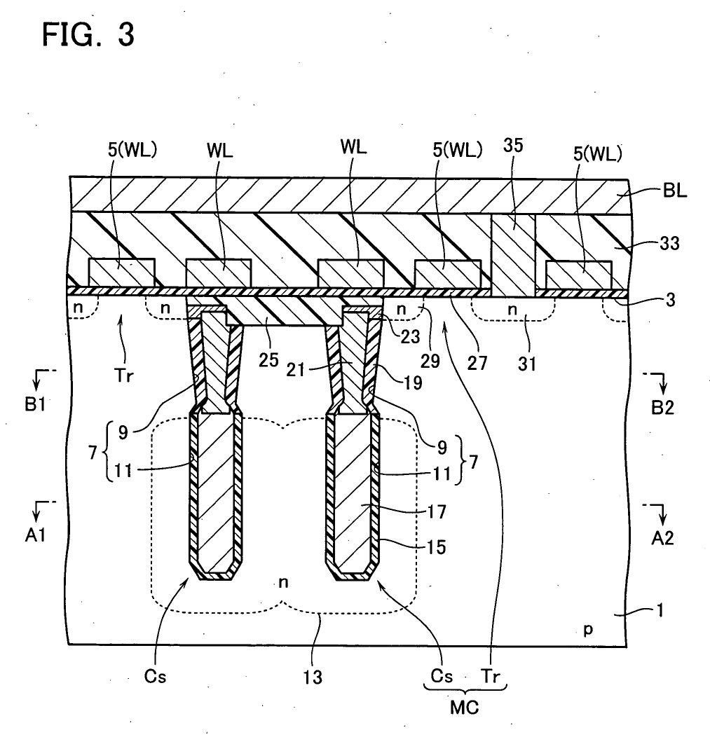

A structure of the memory cell MC according to the first embodiment is described next. FIG. 3 is a longitudinal cross-sectional view of part of the memory cell array according to the first embodiment. The MOS transistor Tr, having a gate electrode 5 formed on a surface 3 of a semiconductor substrate 1, and the capacitor Cs, formed in the semiconductor substrate 1, configure the memory cell MC. The memory cell MC has the following detailed structure.

The p-type semiconductor substrate (such as a silicon substrate) 1 has the surface 3 of a plane orientation {100}. A plurality of deep trenches 7 are formed in the semiconductor substrate 1 as extending from the surface 3 into the semiconductor substrate 1. The trench 7 has a depth of 6-8 μm, for example. The trench 7 has an upper portion 9 above a boundary located almost 2 μm below the surface 3, and a lower portion 11 below the boundary. The upper portion 9 has a side tapered to reduce the width of the trench 7 gradually as approaching from the surface 3 toward inside the semiconductor substrate 1. Accordingly, the width of the trench 7 gradually decreases in the upper portion 9 of the trench 7. To the contrary, the width of the trench 7 is almost constant in the lower portion 11 of the trench.

An n-type impurity region 13 is formed in the semiconductor substrate 1 around the lower portion 11 of the trench. A capacitor insulator 15 is formed on the side of the lower portion 11. A buried conductive member 17 composed of polysilicon is formed on the capacitor insulator 15 as buried in the lower portion 11. The capacitor Cs comprises the impurity region 13 serving as one electrode, the capacitor insulator 15, and the buried conductive member 17 serving as the other electrode.

A collar insulator 19 is formed on the side of the upper portion 9 of the trench. The collar insulator 19 is effective to prevent formation of a parasitic transistor. Accordingly, the collar insulator 19 is thicker than the capacitor insulator 15. A buried wire 21 is formed on the collar insulator 19 as buried in the upper portion 9 of the trench. The buried wire 21 is connected to the buried conductive member 17 in the trench 7. A conductive film 23, covering the collar insulator 19 and the buried wire 21 and contacting with the buried wire 21, is formed on the upper portion 9 of the trench. A device isolation film 25 is formed between adjoining trenches 7 as buried in the surface 3.

A gate insulator 27 of the MOS transistor Tr is formed on the surface 3. The word lines WL are arranged at intervals on the gate insulator. The word line WL located on an active region turns into the gate electrode 5. Therefore, the gate electrode 5 is connected to the word line WL. The active region is a region in the surface 3 where the device isolation film 25 is not formed. A source region 29 and a drain region 31, both n-type, are formed in the active region to configure the MOS transistor. The source region 29 is connected to the conductive film 23.

The source region 29 is a first source/drain region connected to the capacitor Cs. The drain region 31 is a second source/drain region connected to the bit line BL. The source/drain region is an impurity region having at least one of the functions of the source and drain regions.

An interlayer insulator 33 is formed as covering the word lines WL. The bit line BL is formed on the interlayer insulator 33. The bit line BL and the drain region 31 are connected with each other through a bit line contact 35 buried in the interlayer insulator 33.

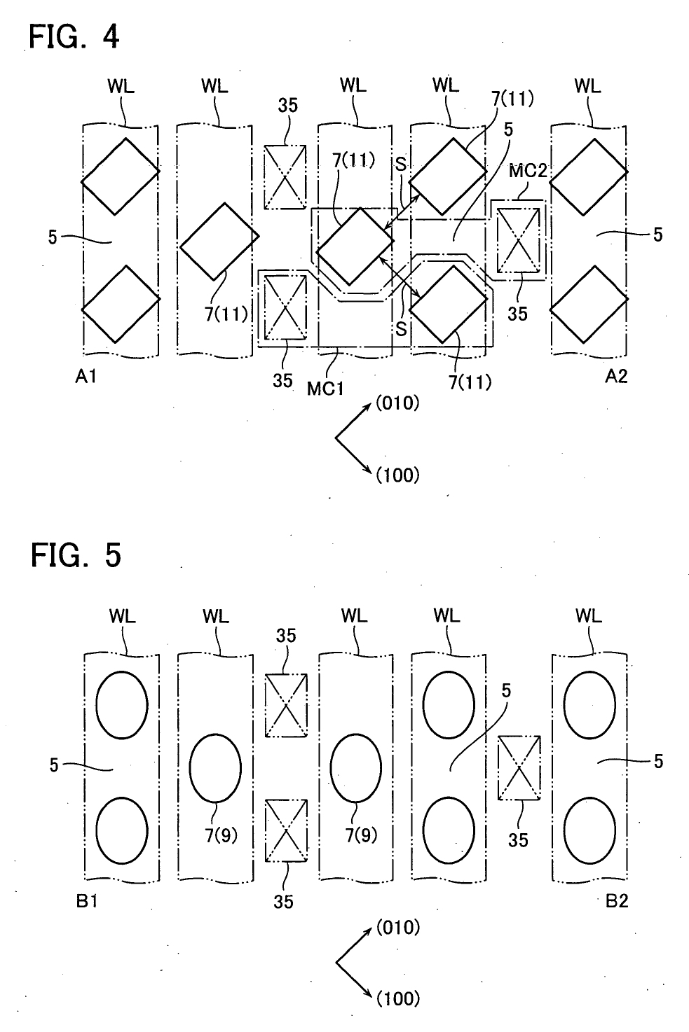

The following description is given to transverse sections of the trench 7. FIG. 4 is a transverse cross-sectional view taken along A1-A2 line in FIG. 3. FIG. 5 is a transverse cross-sectional view taken along B1-B2 line in FIG. 3. The transverse section of the trench 7 is a section obtained by slicing the trench 7 with a plane parallel to the bottom of the semiconductor substrate 1. The transverse section of the upper portion 9 of the trench is oval while the transverse section of the lower portion 11 is rectangular (an example of tetragonal).

The transverse section of the upper portion 9 of the trench has a major axis, which extends in the direction of extension of the word line WL. The transverse sections of the lower portions 11 of the trenches are tilted at the substantially same angle against the direction of extension of the word line WL. The rectangle has a shorter side in the (100) direction and a longer side in the (010) direction. In this case, (klm) represents a specific plane orientation and {klm} represents equivalent planes inclusively. Thus, {100} contains both (100) and (010).

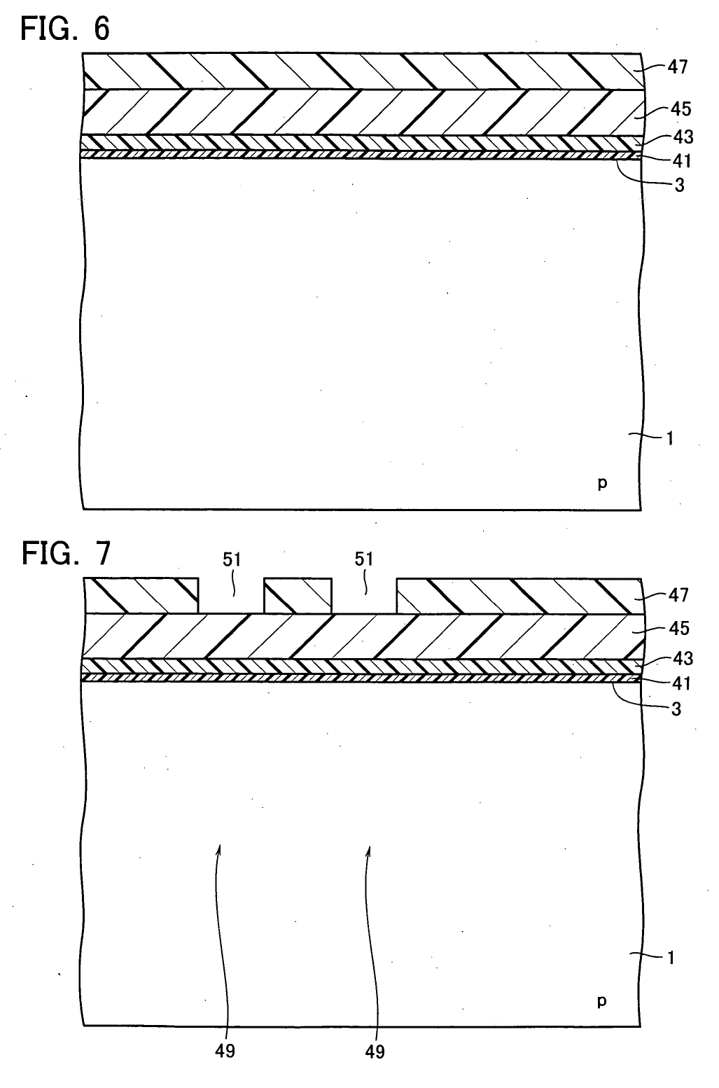

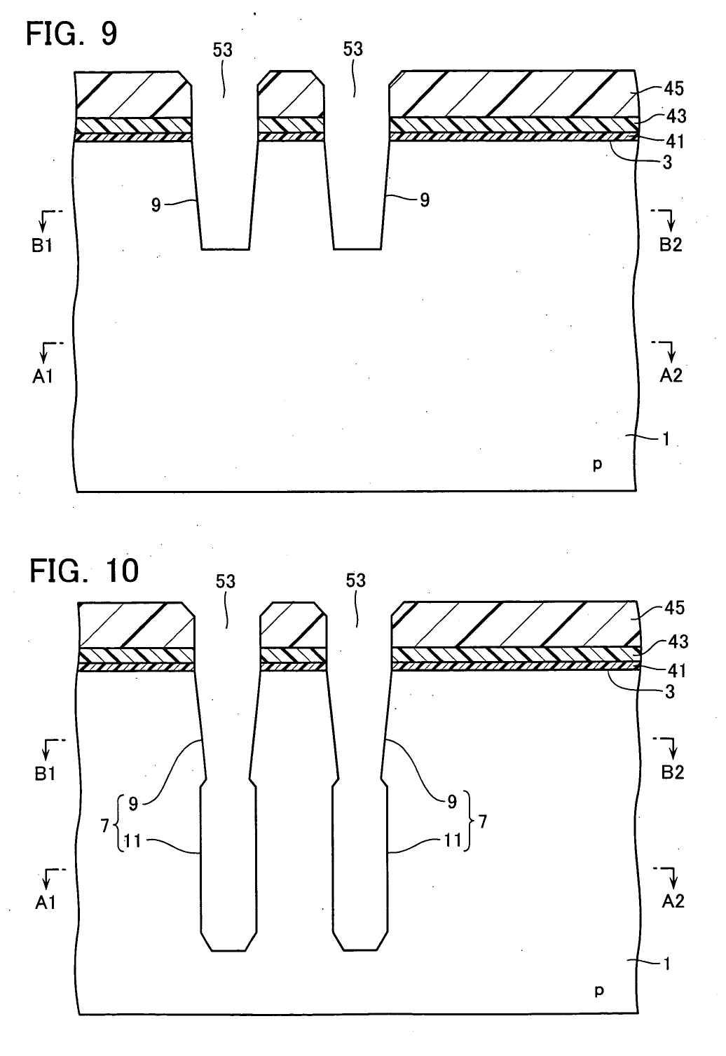

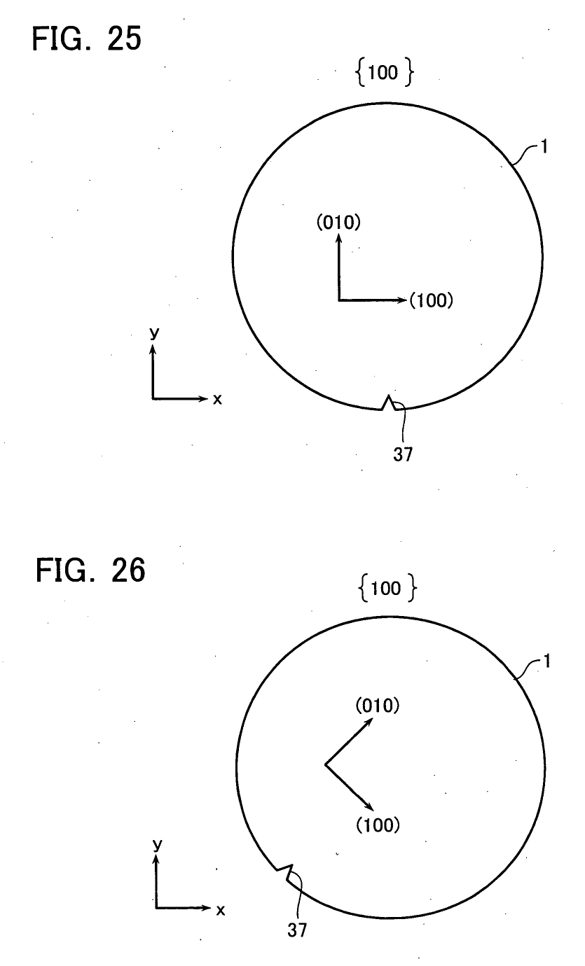

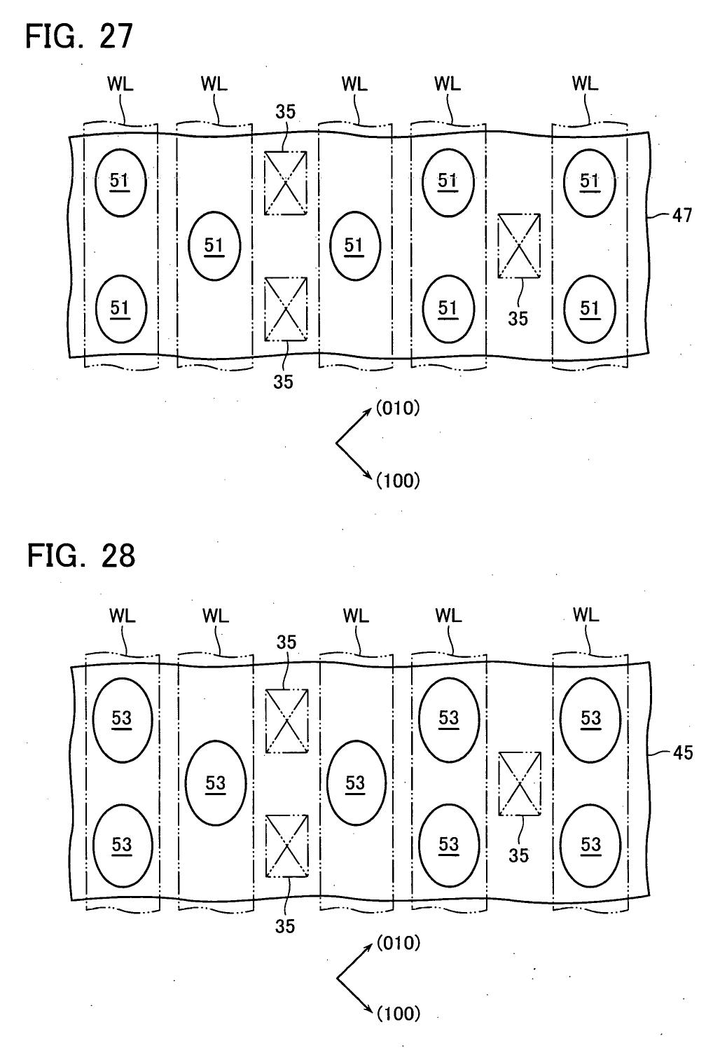

A method of manufacturing the memory cell MC shown in FIG. 3 is described with reference to FIGS. 3-28. FIGS. 6-24 are longitudinal cross-sectional views in a process sequence showing the method of manufacturing the memory cell MC shown in FIG. 3. FIGS. 25 and 26 are plan views of a semiconductor substrate (wafer) for use in formation of the memory cell MC. FIG. 27 is a plan view of the resist shown in FIG. 7. FIG. 28 is a plan view of the mask shown in FIG. 9.

As shown in FIG. 6, the semiconductor substrate 1 is prepared, which is composed of silicon and has the surface 3 of the plane orientation {100}. A process of thermal oxidation is applied to form a silicon oxide film 41 with a thickness of 2 nm on the surface 3. A process of CVD (Chemical Vapor Deposition) is then applied to form a silicon nitride film 43 with a thickness of 220 nm on the silicon oxide film 41. If the silicon nitride film 43 is formed directly on the surface 3, poor adhesion arises between the silicon nitride film 43 and the semiconductor substrate 1 composed of silicon. Therefore, the silicon oxide film 41 is interposed therebetween.

A silicon oxide film 45 with a thickness of 1600 nm is formed next by CVD on the silicon nitride film 43. A process of spin coating is employed to form a film of resist 47 with a thickness of 600 nm on the silicon oxide film 45. The semiconductor substrate 1 with the resist 47 formed thereon is mounted on an exposure apparatus.

An exposure process is described. The semiconductor substrate for use in formation of the semiconductor device such as the memory cell MC is referred to as a wafer. As shown in FIG. 25, while aligning a notch 37 of the wafer (semiconductor substrate 1) with they-axis of the exposure apparatus, the wafer is mounted on the exposure apparatus. The x-axis of the exposure apparatus matches with the (100) direction and the y-axis with the (010) direction. Then, the wafer is rotated 45° in the x-y plane as shown in FIG. 26 and the resist 47 is subjected to exposure and development at this location. Thus, as shown in FIG. 7, the resist 47 is patterned such that the resist 47 has apertures 51 at the locations corresponding to regions 49 for formation of the trenches 7.

FIG. 27 is a plan view of the patterned resist 47. At this stage, the word lines WL and the bit line contacts 35 depicted with double-dotted chain lines are not yet formed.

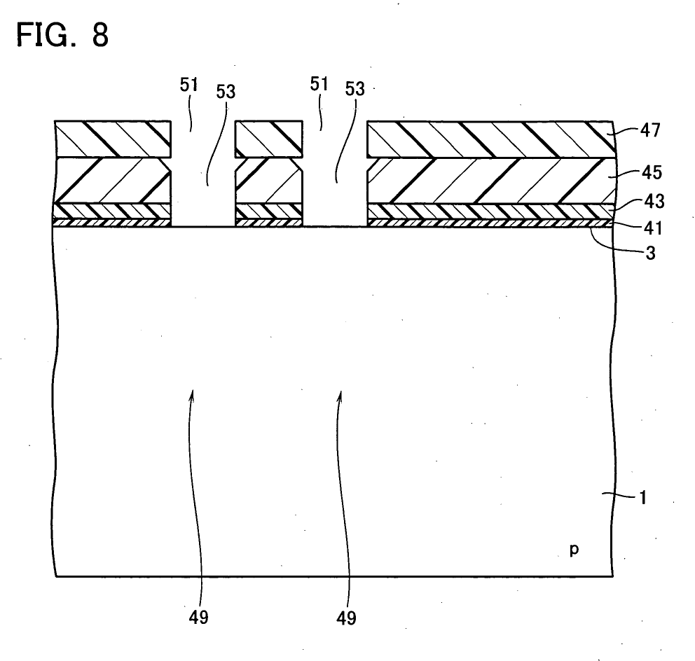

As shown in FIG. 8, with a mask of the patterned resist 47, a process of anisotropic etching such RIE (Reactive Ion Etching) is applied to etch the silicon oxide film 45, the silicon nitride film 43 and the silicon oxide film 41 to bare the surface 3. Through these films, apertures 53 having an oval transverse section are formed. The resist 47 is finally removed.

As shown in FIGS. 9 and 28, with a mask of the silicon oxide film 45, RIE is applied to etch the semiconductor substrate 1 down to a depth of about 2 μm to form the upper portion 9 of the trench. The upper portion 9 of the trench has a side tapered to reduce the width of the trench gradually as approaching from the surface 3 toward inside the semiconductor substrate 1. A specific condition for this etching is given below. The etching gas is a mixed gas containing 230 sccm of HBr, 21 sccm of O₂ and 35 sccm of NF₃, with etching chamber pressure of 150 mTorr and exciting power of 900 W.

As shown in FIG. 10, after formation of the upper portion 9 of the trench, the etching condition is changed to another for etching the semiconductor substrate 1 to form the lower portion 11 of the trench. The lower portion 11 has a side substantially perpendicular to the surface 3 and an almost constant trench width. A specific condition for etching the lower portion 11 is given below. The etching gas is a mixed gas containing 230 sccm of HBr, 8 sccm of O₂ and 17 sccm of NF₃, with etching chamber pressure of 200 mTorr and exciting power of 1600 W.

At the beginning of etching, the transverse section of the trench 7 initially reflects the shape and direction of the aperture 53 shown in FIG. 28. Accordingly, as shown in FIG. 5, the transverse section of the trench 7 is oval with the major axis located in the direction of extension of the word line WL. As the etching is applied to the surface 3 of the plane orientation {100}, however, the etching of the trench 7 may easily proceed in the (110) direction and the (1-10) direction. Therefore, as approaching toward the bottom in the trench, the direction of the transverse section of the trench 7 gradually varies and the shape of the transverse section gradually varies from oval. At a depth of about 2 μm, the shape of the transverse section varies to rectangular (an example of tetragonal) with a shorter side in the (100) direction and a longer side in the (010) direction. Accordingly, the lower portion 11 of the trench has the shape and direction of the transverse section as shown in FIG. 4.

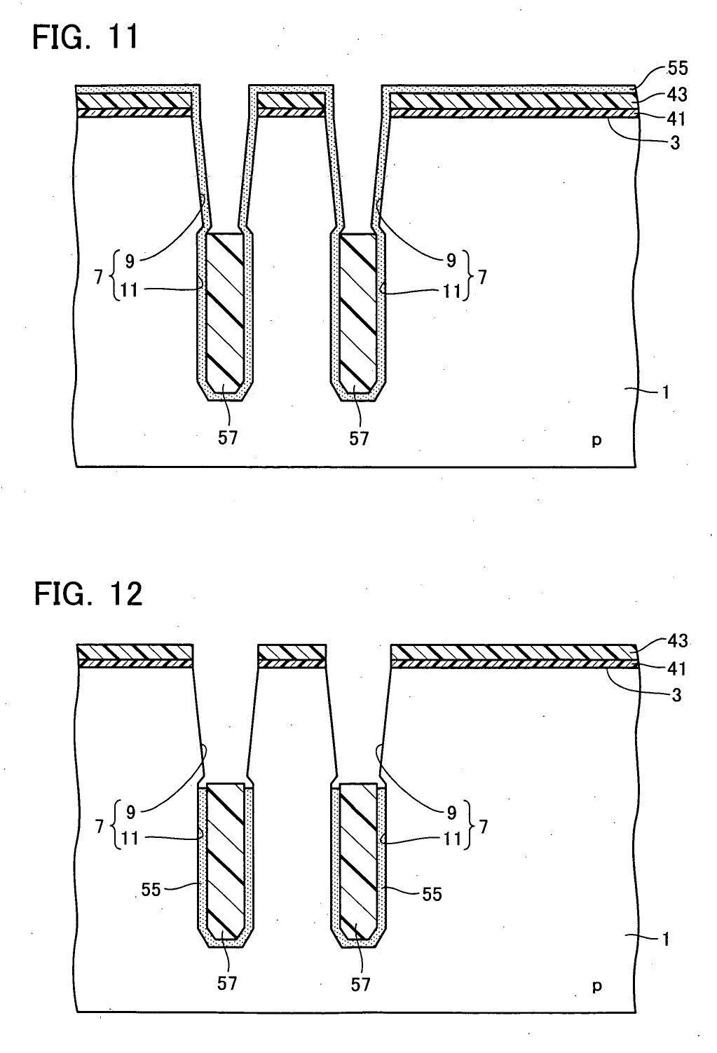

As shown in FIG. 11, a process of hydrofluoric acid-based wet etching is applied to remove the silicon oxide film 45, and CVD is then employed to form an impurity-containing film, such as an AsSG film 55, over the semiconductor substrate 1. Thus, the AsSG film 55 is formed on the side of the trench 7. The AsSG film 55 has a thickness of about 30 nm. A film may serve as the impurity-containing film if it contains As (Arsenic) or P (Phosphorous).

A process of spin coating is employed next to form a film of resist 57 with a thickness of several 1000 nm over the semiconductor substrate 1. The resist 57 is buried in the trenches 7. A process of down flow etching is then applied to remove the resist 57 formed on the silicon nitride film 43 and in the upper portion 9 of the trench to bare the AsSG film 55. The resist 57 is left in the lower portion 11 of the trenches.

As shown in FIG. 12, a process of hydrofluoric acid-based wet etching or down flow etching is applied to remove the AsSG film 55 formed on the silicon nitride film 43 and on the side of the upper portion 9 of the trench. A process of wet etching using a mixed solution of hydrogen peroxide water with sulfuric acid is employed to remove the resist 57 left in the lower portion 11 of the trench.

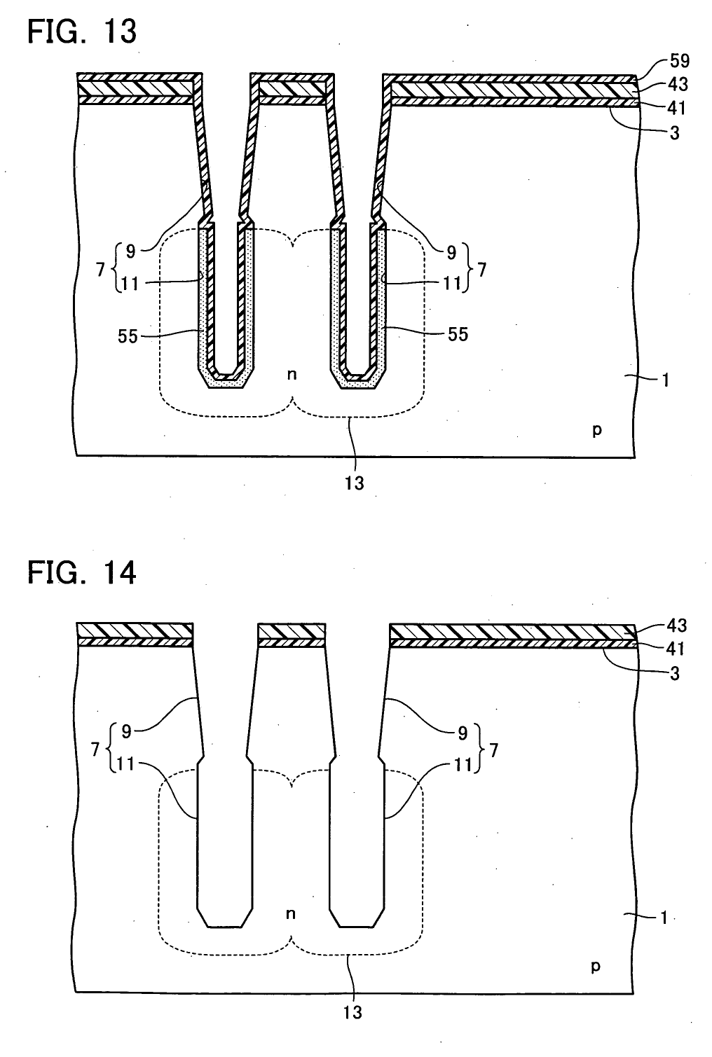

As shown in FIG. 13, a TEOS (Tetraethylorthosilicate) film 59 with a thickness of 20 nm is formed over the semiconductor substrate 1 by CVD as covering the side of the trench 7. Subsequently, As contained in the AsSG film 55 is diffused into the semiconductor substrate 1 around the lower portion 11 of the trench by thermal oxidation at about 1000° C., thereby forming the n-type impurity region 13 serving as one electrode of the capacitor. The presence of the TEOS film 59 is effective to prevent As from diffusing into the semiconductor substrate 1 around the upper portion 9 of the trench. A process of hydrofluoric acid-based wet etching is employed next to remove the TEOS film 59 and the AsSG film 55 as shown in FIG. 14.

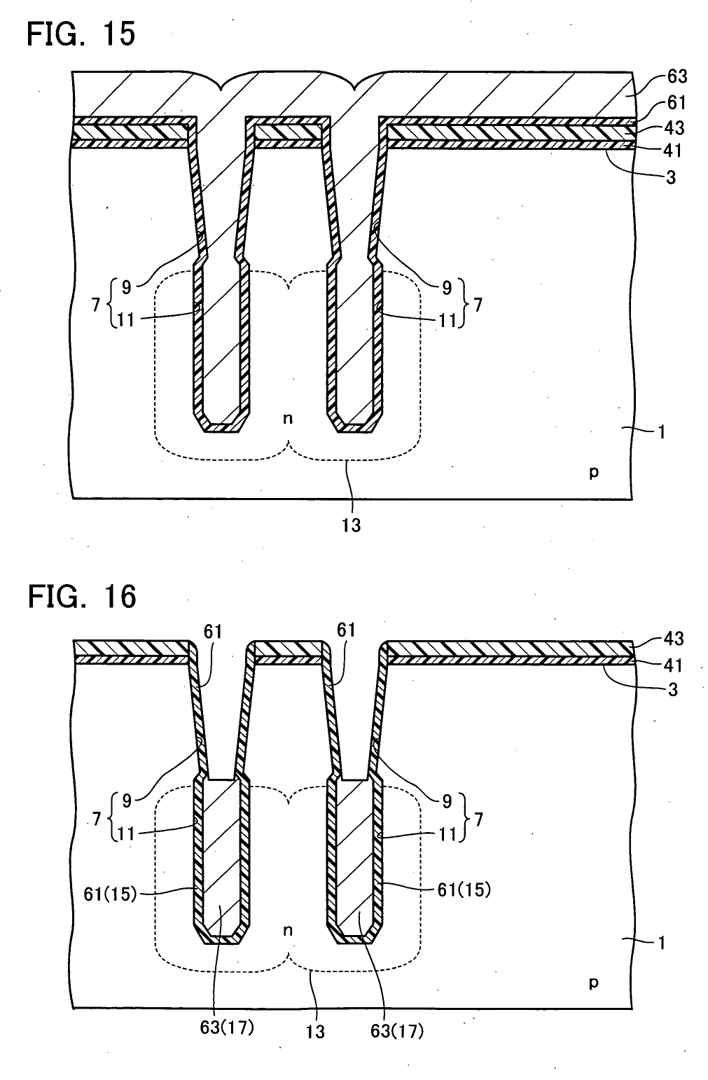

As shown in FIG. 15, an insulator 61 with a thickness of several 10 nm is formed over the semiconductor substrate 1 by CVD such that the insulator 61 is formed on the side of the trench 7. The insulator 61 serves as the capacitor insulator. A NO film (layered film of nitride and oxide), and a dielectric film may be employed as the insulator 61. Then, CVD is employed to form a conductive film 63 with a thickness of several 100 nm over the semiconductor substrate 1 as buried in the trench 7. An As-doped polysilicon film may serve as the conductive film 63.

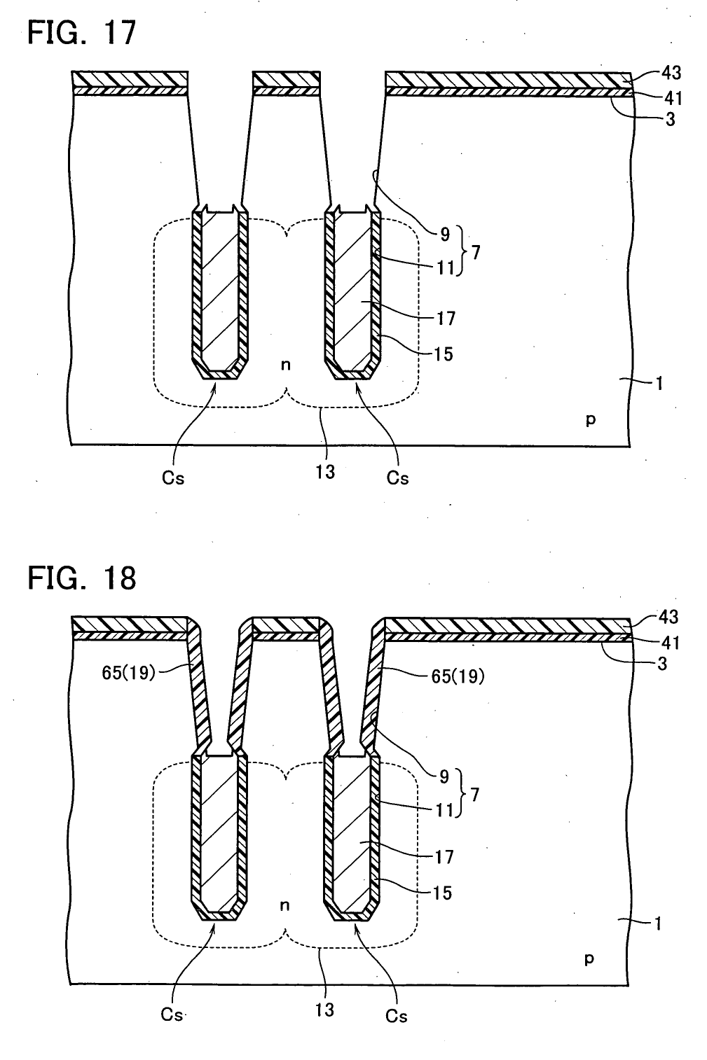

As shown in FIG. 16, a certain planarization process such as CMP (Chemical Mechanical Polishing) or a certain etching process is applied to remove the conductive film 63 except for the conductive film 63 left on the lower portion 11 of the trench. The conductive film 63 left on the lower portion 11 of the trench serves as the buried conductive member 17 or the other electrode of the capacitor. The insulator 61 located between the buried conductive member 17 and the lower portion 11 of the trench serves as the capacitor insulator 15. During this process, the insulator 61 formed on the silicon nitride film 43 is removed. Then, a phosphoric acid-based wet etching is employed to remove the insulator 61 formed on the side of the upper portion 9 of the trench as shown in FIG. 17.

As shown in FIG. 18, CVD is employed to form a TEOS film 65 over the semiconductor substrate 1. Then, RIE is applied to etch the TEOS film 65 entirely except for the TEOS film 65 left on the side of the upper portion 9 of the trench, which serves as the collar insulator 19 in FIG. 3. The collar insulator 19 is effective to prevent formation of a parasitic transistor and requires a sufficient thickness. Accordingly, the collar insulator 19 has a thickness (for example, 25-35 nm) larger than the thickness (for example, 4-6 nm) of the capacitor insulator 15.

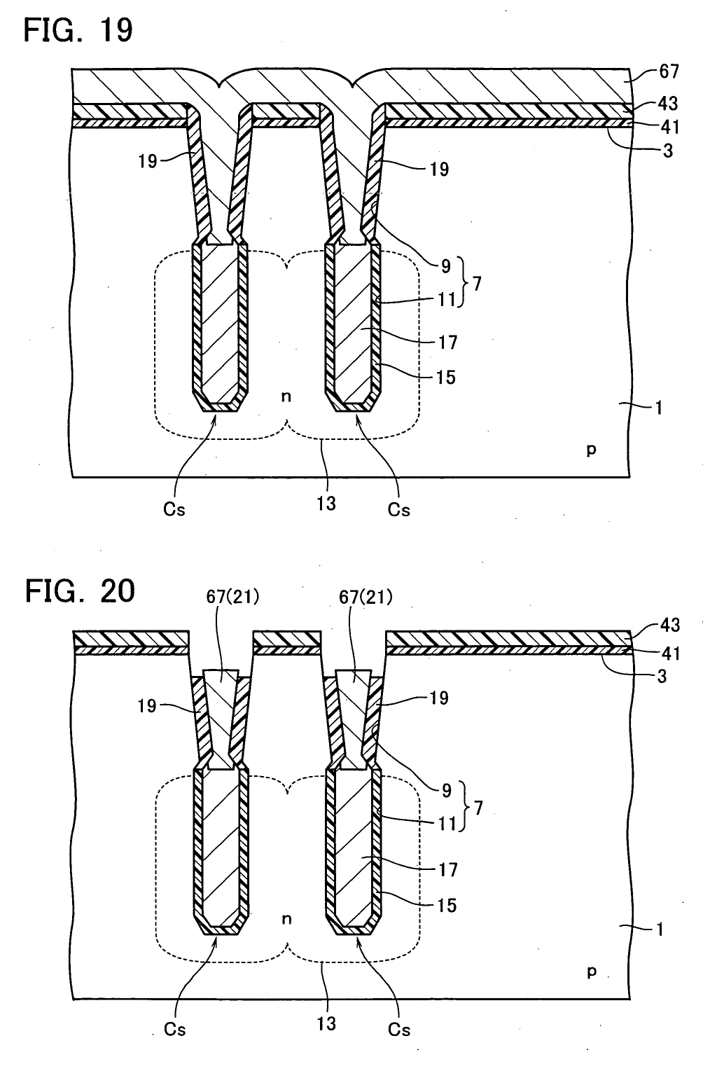

As shown in FIG. 19, CVD is employed to form a conductive film 67 with a thickness of several 100 nm over the semiconductor substrate 1 as buried in the upper portion 9 of the trench. An As-doped polysilicon film may serve as the conductive film 67.

As shown in FIG. 20, CMP or the like is applied to remove the conductive film 67 down to a certain depth in the upper portion 9 of the trench. The conductive film 67 left in the upper portion 9 of the trench serves as the buried wire 21. This etching bares part of the collar insulator 19. The bared collar insulator 19 is removed using a phosphoric acid-based wet etching.

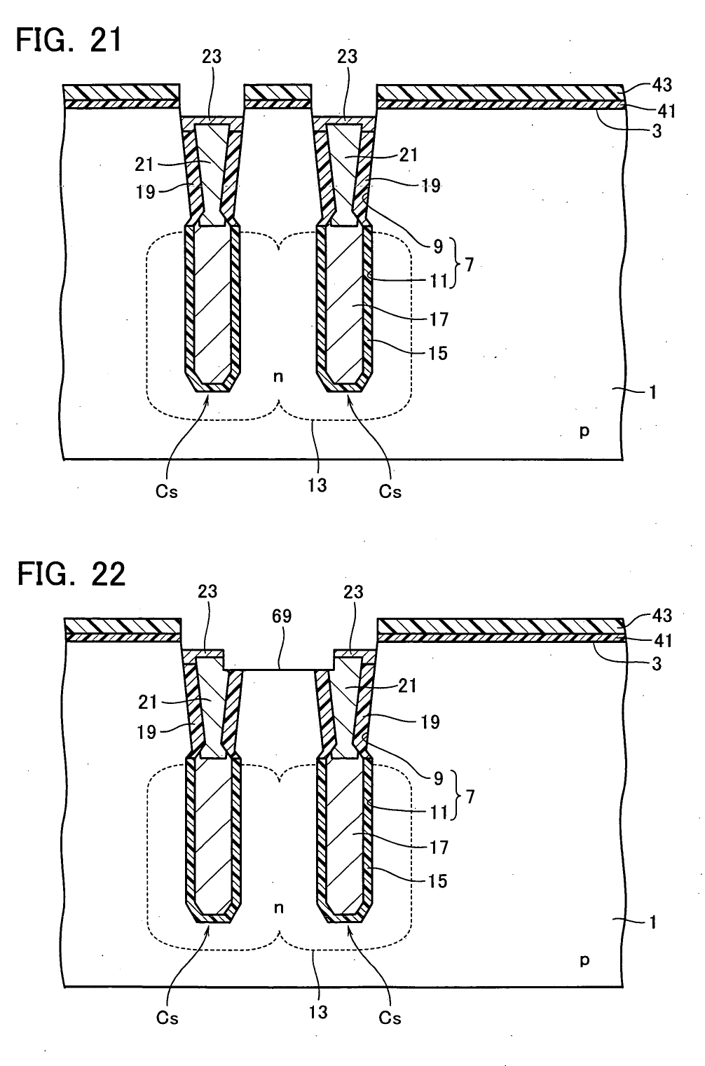

As shown in FIG. 21, CVD is employed to form the conductive film 23 with a thickness of several 100 nm over the semiconductor substrate 1. Then, CMP or the like is applied to remove the conductive film 23 to bare part of the side of the upper portion 9 of the trench.

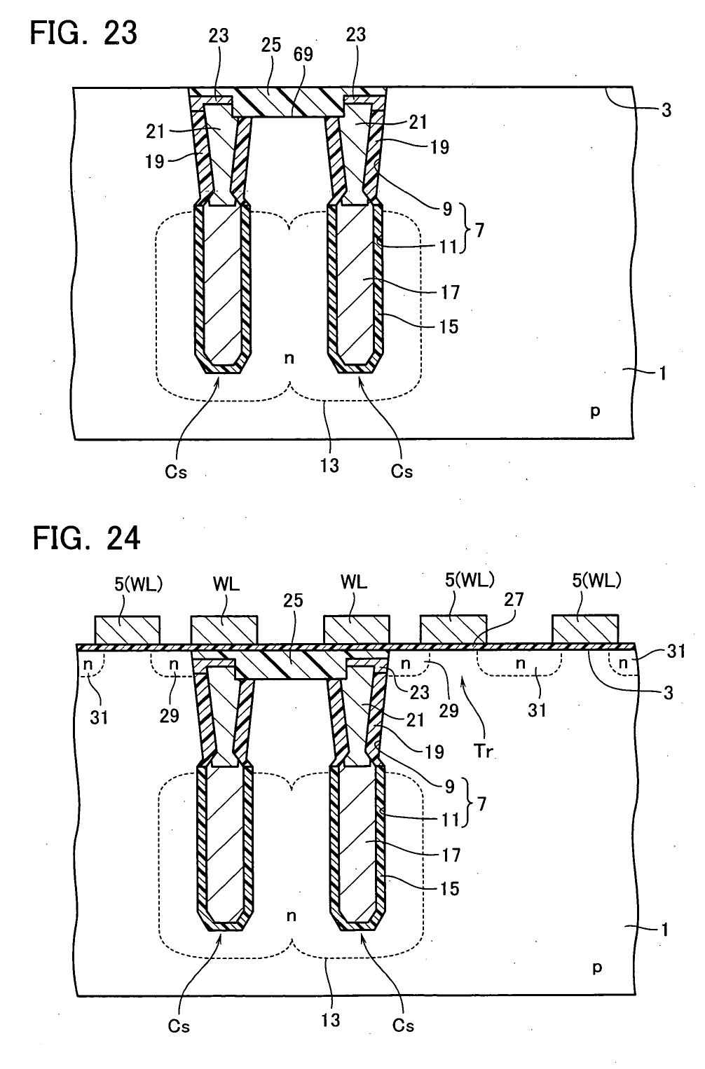

As shown in FIG. 22, a shallow trench 69 is formed between adjoining trenches 7 as spanning from one to the other. Then, as shown in FIG. 23, CVD is applied to form an insulator (such as TEOS film) with a thickness of several 100 nm over the semiconductor substrate 1 as buried in the trench 69. Subsequently, CMP or the like is employed to remove the insulator formed on the surface 3, thereby forming the device isolation film 25 in the trench 69.

As shown in FIG. 24, thermal oxidation is applied to form the gate insulator 27 with a thickness of 8 nm over the surface 3, and the word lines WL are patterned thereon. The word lines WL are composed of a polysilicon film or a layered film of polysilicon and tungsten silicide. With a mask of the word lines WL, n-type ions are implanted into the semiconductor substrate 1 to form the source regions 29 and the drain regions 31, thereby completing the MOS transistor Tr. As shown in FIG. 3, the interlayer insulator 33, the bit line contacts 35 and the bit lines BL are formed to complete the memory cell MC according to the first embodiment.

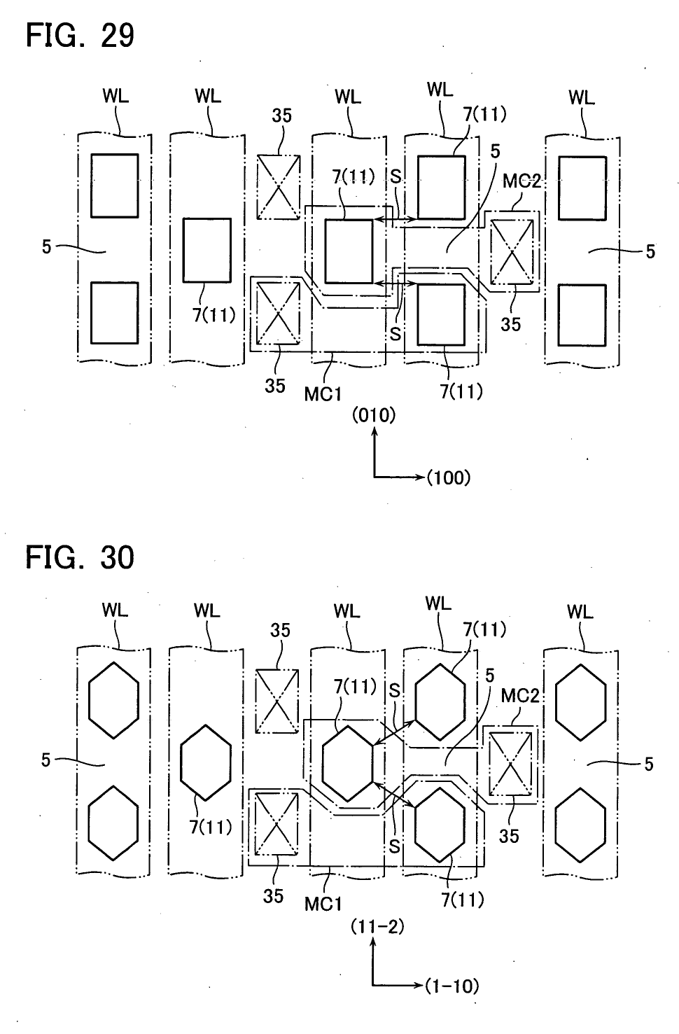

A primary effect of the first embodiment is described in comparison with a comparative example. FIG. 29 is a transverse cross-sectional view of a lower portion 11 of a trench according to the comparative example and corresponds to FIG. 4. In the comparative example, the wafer (semiconductor substrate 1) is not rotated 45° in the x-y plane as shown in FIG. 25 when the resist is subjected to exposure and development. Therefore, the transverse section of the lower portion 11 of the trench is rectangular with a longer side in the (010) direction and a shorter side in the (100) direction.

The memory cell MC of either the first embodiment or the comparative example includes the transistor Tr and the capacitor Cs that is buried in a trench 7 formed beneath a word line WL adjacent to a word line WL for control of the transistor Tr as shown in FIG. 3. In addition, as shown in FIGS. 4 and 29, two word lines WL and one bit line contact 35 are alternately arranged in the direction of arrangement of the word lines WL. In memory cells MC1, 2 arranged adjacent to each other, the trench 7 with the capacitor of the memory cell MC1 buried therein is formed beneath the word line WL associated with the memory cell MC2. The trench 7 with the capacitor of the memory cell MC2 buried therein is formed beneath the word line WL associated with the memory cell MC1.

In the lower portion 11 of the trench according to the comparative example shown in FIG. 29, the transverse section of the trench 7 is not tilted against the direction of extension of the word line WL. In such the case, a space S between the trenches 7 is made relatively small. As a result, the space S between the trenches 7 is not given a sufficient margin and may make incomplete separation between the trenches 7 possibly.

To the contrary, in the first embodiment shown in FIG. 4, the transverse sections of the trenches 7 are tilted at the substantially same angle against the direction of extension of the word line WL. Accordingly, the space S between the trenches 7 can be made relatively large. As a result, the space S between the trenches 7 is given a significant margin and can achieve complete separation between the trenches 7.

In the first embodiment, the resist is subjected to exposure at a 45°-rotated location of the wafer (semiconductor substrate 1) as shown in FIG. 26. The exposure of the resist at about 35-550 rotated locations may also achieve the similar effect.

Even if the wafer is rotated 135°, 225° and 315°, the shape and direction of the transverse section similar to that on the 45°-rotated wafer can be achieved of course. Also in this case, the wafer may be rotated for exposure of the resist within a range where the transverse section in the direction tilted about 35-550 can be obtained.

### Second Embodiment

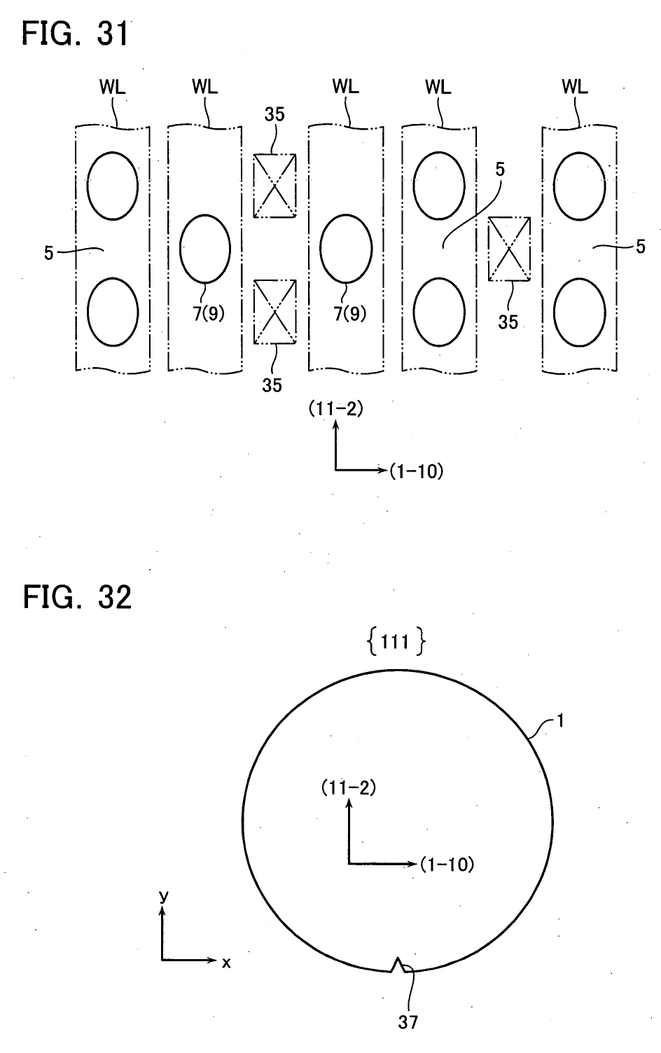

A semiconductor device according to a second embodiment is mainly characterized in that a trench having a hexagonal transverse section is formed in a semiconductor substrate having a surface of a plane orientation {111}, and a DRAM capacitor is formed in the trench. The second embodiment is described mainly about the differences from the first embodiment. FIG. 30 is a transverse cross-sectional view of a lower portion 11 of a trench according to the second embodiment and corresponds to FIG. 4. FIG. 31 is a transverse cross-sectional view of an upper portion 9 of the trench according to the second embodiment and corresponds to FIG. 5.

In this case, {111} represents equivalent planes inclusively and contains both (11-2) and (1-10). The word lines WL are extended in the (11-2) direction and arranged in the (1-10) direction. The transverse section of the lower portion 11 of the trench is hexagonal elongated in the direction of extension of the word line WL. The transverse section of the upper portion 9 of the trench is oval with the major axis located in the direction of extension of the word line WL. That the transverse section of the lower portion 11 of the trench according to the second embodiment is hexagonal is because the trench 7 is formed in the semiconductor substrate having the surface of the plane orientation {111}.

A method of forming the trench 7 according to the second embodiment is described. Like in the first embodiment, the silicon oxide film 41, the silicon nitride film 43, the silicon oxide film 45 and the resist 47 are formed in turn on the surface 3 of the semiconductor substrate 1 as shown in FIG. 6. In the second embodiment, however, the plane orientation of the surface 3 of the semiconductor substrate 1 is {111}.

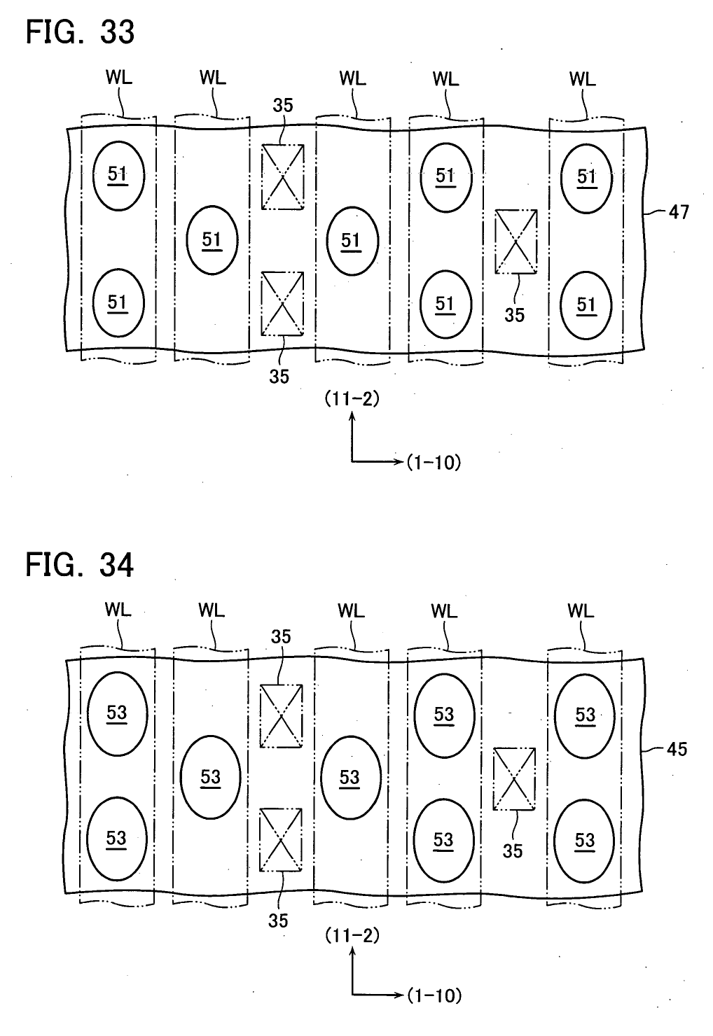

As shown in FIG. 32, while aligning the notch 37 of the wafer (semiconductor substrate 1) with the y-axis of the exposure apparatus, the wafer is mounted on the exposure apparatus. The x-axis of the exposure apparatus matches with the (1-10) direction and the y-axis with the (11-2) direction. In the second embodiment, the wafer is not rotated 45° and the resist 47 is subjected to exposure at a location shown in FIG. 32. FIG. 33 is a plan view of the patterned resist 47 and corresponds to FIG. 27. FIG. 34 is a plan view of the silicon oxide film 45 patterned with a mask of the resist 47 of FIG. 33 and corresponds to FIG. 28.

Then, like in the first embodiment, the silicon oxide film 45 shown in FIG. 34 is employed as a mask to form the trenches 7. At the beginning of etching, reflecting the shape of the aperture of the mask, the transverse section of the trench 7 is initially oval with the major axis located in the direction of extension of the word line WL. As the etching proceeds, the shape of the transverse section of the trench 7 gradually varies from oval and, at a depth of about 2 μm, it varies to hexagonal elongated in the direction of extension of the word line WL. Accordingly, the transverse section of the lower portion 11 of the trench becomes hexagonal elongated in the direction of extension of the word line WL as shown in FIG. 30. The foregoing is associated with the method of forming the trench 7 according to the second embodiment. Thereafter, the same method as in the first embodiment is employed to form the capacitor Cs and the MOS transistor Tr.

As shown in FIG. 30, the transverse section of the lower portion 11 of the trench according to the second embodiment is hexagonal elongated in the direction of extension of the word line WL. Accordingly, like in the first embodiment, the space S between the trenches 7 can be made relatively large. Thus, the interval between the trenches 7 can be given a margin sufficient to completely isolate the trenches 7 from one another.

### Third Embodiment

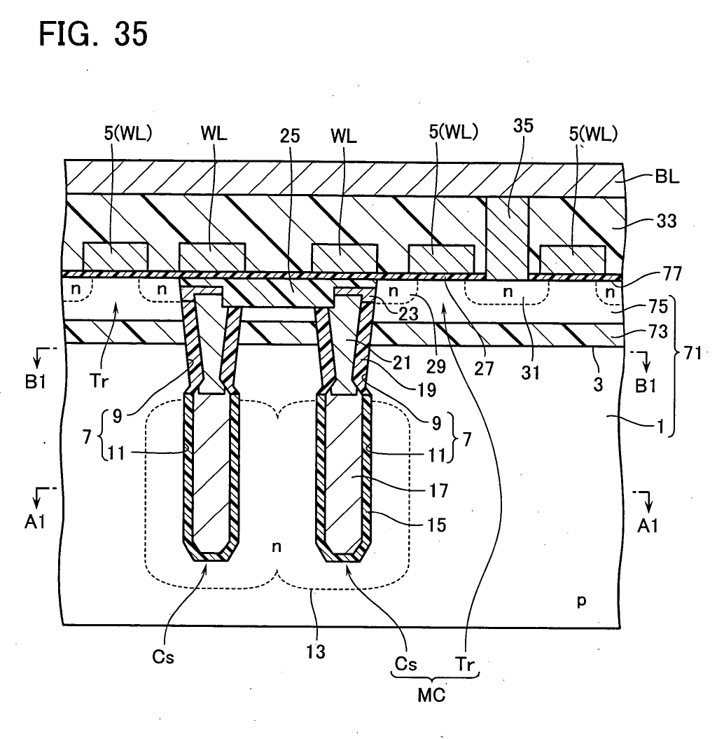

A semiconductor device according to a third embodiment is mainly characterized in that a DRAM capacitor is formed in a trench having a hexagonal transverse section provided in an SOI (Silicon On Insulator) substrate. The third embodiment is described mainly about the differences from the preceding embodiments. FIG. 35 is a longitudinal cross-sectional view of part of a memory cell array according to the third embodiment and corresponds to FIG. 3. The SOI substrate 71 comprises a semiconductor substrate 1 having a surface 3 of a plane orientation {111}, an insulating layer 73 composed of silicon oxide formed on the surface 3, and a single crystal semiconductor layer 75 composed of silicon formed on the insulating layer 73. The single crystal semiconductor layer 75 has a surface 77 of the plane orientation {100}. The SOI substrate 71 can be produced by bonding a silicon substrate having a surface of the plane orientation {100} and a silicon substrate having a surface of a plane orientation {111} together. The upper portion 9 of the trench extends into the semiconductor substrate 1 through the single crystal semiconductor layer 75 and the insulating layer 73. The lower portion 11 extends much deeper into the semiconductor substrate 1. A transverse cross-sectional view taken along A1-A2 line of the SOI substrate 71 is shown in FIG. 30 and a transverse cross-sectional view taken along B1-B2 line is shown in FIG. 31.

The MOS transistor Tr has the gate electrode 5 formed on the gate insulator 27 above the single crystal semiconductor layer 75. The source region 29 and the drain region 31 of the MOS transistor Tr are formed in the single crystal semiconductor layer 75 as spaced from each other.

In the third embodiment, the trenches 7 are formed in the semiconductor substrate 1 having the surface 3 of the plane orientation {111}. Accordingly, it is possible to completely isolate the trenches 7 from each other like in the second embodiment. In addition, the MOS transistor Tr is formed in the single crystal semiconductor layer 75 having the surface 77 of the plane orientation {100}. Accordingly, it is possible to keep the performance of the MOS transistor Tr.

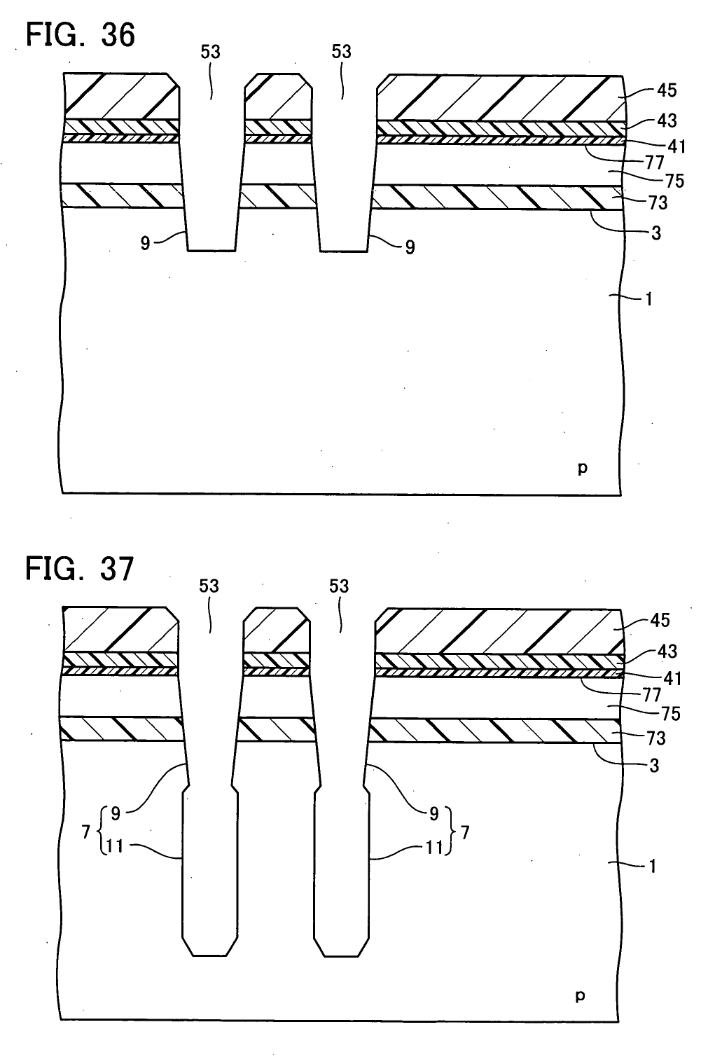

A method of forming the trench 7 according to the third embodiment is briefly described with reference to FIGS. 36 and 37. FIGS. 36 and 37 are longitudinal cross-sectional views showing processes of forming the trench 7 in turn. FIG. 36 corresponds to FIG. 9, and FIG. 37 corresponds to FIG. 10. The method of forming the upper portion 9 of the trench described with respect to FIG. 9 is employed to form the upper portion 9 of the trench. The upper portion extends into the semiconductor substrate 1 through the single crystal semiconductor layer 75 and the insulating layer 73 as shown in FIG. 36. Then, the method of forming the lower portion 11 of the trench described with respect to FIG. 10 is employed to form the lower portion 11 of the trench in the semiconductor substrate 1 as shown in FIG. 37. Thereafter, the method similar to that in the first embodiment is employed to form the capacitor Cs and the MOS transistor Tr.

What is claimed is:

1. A semiconductor device, comprising:
a semiconductor substrate having a surface of a plane orientation {100}; and
a plurality of memory cells formed on said semiconductor substrate, said memory cells each including
a capacitor formed in a trench extending from said surface into said semiconductor substrate, and
a transistor having a first source/drain region connected to said capacitor, a second source/drain region formed apart from said first source/drain region as leaving an interval therebetween and connected to a bit line, and a gate electrode formed over said interval between said first and second source/drain regions and connected to a word line,
wherein a transverse section of at least part of said trench is tetragonal, and
wherein transverse sections of said trenches in said memory cells are tilted at the substantially same angle against a direction of extension of said word line.

2. The semiconductor device according to claim 1, wherein said memory cells include memory cells adjoining, one to the other,
wherein a trench for formation of a capacitor of said one memory cell is located beneath a word line connected to a gate electrode of said the other memory cell, and
wherein a trench for formation of a capacitor of said the other memory cell is located beneath a word line connected to a gate electrode of said one memory cell.

3. The semiconductor device according to claim 1, wherein said transverse section of said trench is rectangular.

4. The semiconductor device according to claim 1, wherein said trench has a depth of 6-8 μm below said surface.

5. The semiconductor device according to claim 1, wherein said capacitor is formed in a lower portion of said trench,
wherein said capacitor includes
an impurity region formed in said semiconductor substrate around said lower portion of said trench to serve as one electrode of said capacitor,
a capacitor insulator formed on a side of said lower portion of said trench, and
a buried conductive member formed on said capacitor insulator as buried in said lower portion of said trench to serve as the other electrode of said capacitor, and
wherein said memory cells each further include
a collar insulator formed on a side of an upper portion of said trench, and
a buried wire formed on said collar insulator as buried in said upper portion of said trench and connected to said buried conductive member in said trench.

6. The semiconductor device according to claim 5, wherein said side of said upper portion of said trench is tapered to reduce a width of said trench gradually as approaching from said surface toward inside semiconductor substrate, and
wherein said width of said trench is almost constant at said lower portion of said trench.

7. The semiconductor device according to claim 5, wherein a transverse section of said upper portion of said trench is oval while a transverse section of said lower portion of said trench is rectangular.

8. The semiconductor device according to claim 1, wherein said transverse section of said trench varies from oval to rectangular as approaching from said surface toward inside semiconductor substrate.

9. The semiconductor device according to claim 1, wherein said transverse section of said trench varies to rectangular at a location 2 μm or deeper in said trench below said surface.

10. The semiconductor device according to claim 1, wherein said angle is 35-55°.

11. A semiconductor device, comprising:
a semiconductor substrate having a surface of a plane orientation {111}; and
a plurality of memory cells formed on said semiconductor substrate, said memory cells each including
a capacitor formed in a trench extending from said surface into said semiconductor substrate, and
a transistor having a first source/drain region connected to said capacitor, a second source/drain region formed apart from said first source/drain region as leaving an interval therebetween and connected to a bit line, and a gate electrode formed over said interval between said first and second source/drain regions and connected to a word line,
wherein a transverse section of at least part of said trench is hexagonal elongated in a direction of extension of said word line.

12. The semiconductor device according to claim 11, wherein said memory cells include memory cells adjoining, one to the other,
wherein a trench for formation of a capacitor of said one memory cell is located beneath a word line connected to a gate electrode of said the other memory cell, and
wherein a trench for formation of a capacitor of said the other memory cell is located beneath a word line connected to a gate electrode of said one memory cell.

13. The semiconductor device according to claim 11, wherein said trench has a depth of 6-8 μm below said surface.

14. The semiconductor device according to claim 11, further comprising:
an insulating layer formed on said semiconductor substrate; and
a single crystal semiconductor layer formed on said insulating layer,
wherein said trench extends through said single crystal semiconductor layer and said insulating layer into said semiconductor substrate, and
wherein said transistor is formed in said single crystal semiconductor layer.

15. The semiconductor device according to claim 14, wherein said single crystal semiconductor layer has a surface of a plane orientation {100}.

16. The semiconductor device according to claim 11, wherein said capacitor is formed in a lower portion of said trench,
wherein said capacitor includes
an impurity region formed in said semiconductor substrate around said lower portion of said trench to serve as one electrode of said capacitor,
a capacitor insulator formed on a side of said lower portion of said trench, and
a buried conductive member formed on said capacitor insulator as buried in said lower portion of said trench to serve as the other electrode of said capacitor, and
wherein said memory cells each further include
a collar insulator formed on a side of an upper portion of said trench, and
a buried wire formed on said collar insulator as buried in said upper portion of said trench and connected to said buried conductive member in said trench.

17. The semiconductor device according to claim 16, wherein said side of said upper portion of said trench is tapered to reduce a width of said trench gradually as approaching from said surface toward inside semiconductor substrate, and
wherein said width of said trench is almost constant at said lower portion of said trench.

18. The semiconductor device according to claim 16, wherein a transverse section of said upper portion of said trench is oval while a transverse section of said lower portion of said trench is hexagonal.

19. The semiconductor device according to claim 11, wherein said transverse section of said trench varies from oval to hexagonal as approaching from said surface toward inside semiconductor substrate.

20. The semiconductor device according to claim 11, wherein said transverse section of said trench varies to hexagonal at a location 2 μm or deeper in said trench below said surface.
